(19) United States
(12) Patent Application Publication
(10) Pub. No.: US 2026/0333656 A1
(43) Pub. Date: Oct. 22, 2026

(54) SRAM OPTIMIZATION THROUGH STI HARD MASKS AND THE METHODS OF FORMING THE SAME

(71) Applicant: Taiwan Semiconductor Manufacturing Co., Ltd., Hsinchu (TW)

(72) Inventors: Chia-Hao Pao, Kaohsiung City (TW); Kian-Long Lim, Hsinchu (TW); Ping-Wei Wang, Hsinchu (TW)

(21) Appl. No.: 19/725,313

(22) Filed: Jun. 30, 2026

Related U.S. Application Data
(63) Continuation of application No. 18/809,848, filed on Aug. 20, 2024.

(51) Int. Cl. H10B 10/00; H10D 30/01; H10D 30/43; H10D 30/67; H10D 62/10; H10W 10/00; H10W 10/17

(52) U.S. Cl. CPC H10B 10/125; H10D 30/014; H10D 30/43; H10D 30/6735; H10D 30/6757; H10D 62/121; H10W 10/014; H10W 10/17

(57) ABSTRACT

A method includes forming a shallow trench isolation region in a semiconductor substrate, forming a first protruding fin and a second protruding fin higher than, and on opposing sides of, the shallow trench isolation region, and forming a hard mask over the shallow trench isolation region. The hard mask includes a first portion closer to the first protruding fin and overlapping a first part of the shallow trench isolation region, and a second portion closer to the second protruding fin and overlapping a second part of the shallow trench isolation region. The method further includes patterning the hard mask to remove the second portion of the hard mask and leaving the first portion of the hard mask over the first part of the shallow trench isolation region, and forming a gate stack over the first portion of the hard mask.

### PRIORITY CLAIM AND CROSS-REFERENCE

This application is a continuation of U.S. patent application Ser. No. 18/809,848, filed Aug. 20, 2024 and entitled “SRAM OPTIMIZATION THROUGH STI HARD MASKS AND THE METHODS OF FORMING THE SAME,” which applications is hereby incorporated herein by reference.

### BACKGROUND

Static Random-Access Memory (SRAM) is commonly used in integrated circuits. SRAM cells have the advantageous feature of holding data without a need for refreshing. With the increasing demanding requirement to the speed of integrated circuits, the read speed and write speed of SRAM cells also become more important. Power consumption also needs to be reduced. With the increasingly down-scaling of the already very small SRAM cells, however, such requests are difficult to fulfill.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a circuit schematic of a SRAM cell in accordance with some embodiments.

FIG. 2 illustrates a schematic top view of an intermediate stage in the formation of two SRAM cells in accordance with some embodiments.

FIG. 3 through FIGS. 20A, 20B, 20C, and 20D illustrate the views of intermediate stages in the formation of a SRAM cell in accordance with some embodiments.

FIG. 21 illustrates a schematic top view of two SRAM cells in accordance with some embodiments.

FIG. 22 illustrates a process flow for forming a SRAM cell in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Static Random-Access Memory (SRAM) cell and the method of forming the same are provided. In accordance with some embodiments, in the formation of the SRAM cells, a hard mask is formed adjacent to pass-gate transistors. The hard mask is not formed adjacent to pull-up and pull-down transistors. In accordance with some embodiments in which disposable interposers (such as Disposable Oxide Interposers (DOIs)) are used, when the disposable interposers are removed in order to form replacement gates, the Shallow Trench Isolation (STI) regions adjacent to the pass-gate transistors are protected by the hard mask and are not recessed. The STI regions adjacent to the pull-up transistors and pull-down transistors are not protected by the hard mask, and are recessed.

Accordingly, the replacement gate stacks of the pull-up transistors and pull-down transistors extend lower than the replacement gate stacks of the pass-gate transistors. The pull-up transistors and pull-down transistors thus may have better gate control, while the pass-gate transistors may have reduced bit-line capacitance. Accordingly, the performance of the pass-gate transistors may be tuned separately from the tuning of the performance of the pull-up transistors and pull-down transistors.

The Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

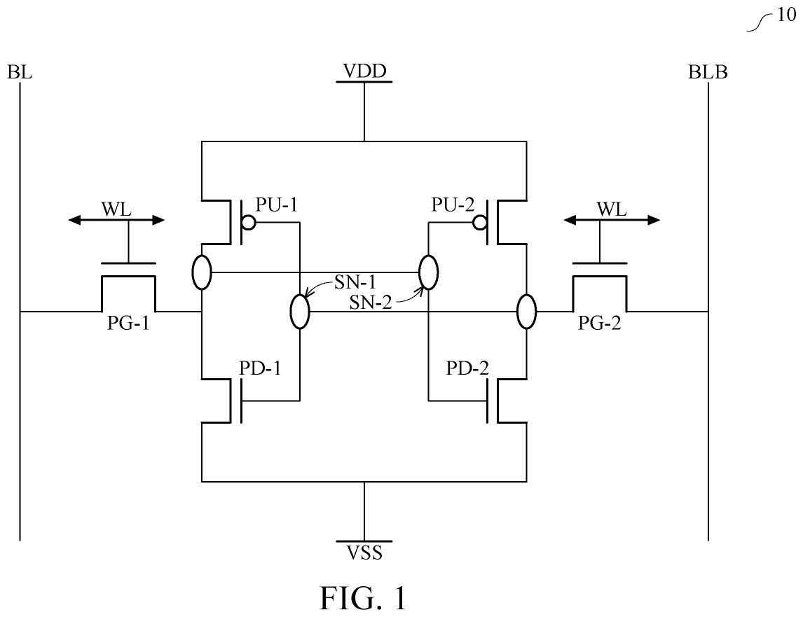

FIG. 1 illustrates a circuit diagram of SRAM cell 10 in accordance with some embodiments. SRAM cell 10 includes pull-up transistors PU-1 and PU-2, which are P-type Metal-Oxide-Semiconductor (PMOS) transistors. SRAM cell 10 further includes pull-down transistors PD-1 and PD-2 and pass-gate transistors PG-1 and PG-2, which are N-type Metal-Oxide-Semiconductor (NMOS) transistors. The gates of pass-gate transistors PG-1 and PG-2 are controlled by word-line WL that determines whether SRAM cell 10 is selected or not.

A latch formed of pull-up transistors PU-1 and PU-2 and pull-down transistors PD-1 and PD-2 stores a bit, wherein the complementary values of the bit are stored in storage nodes SN-1 and SN-2. The stored bit can be written into or read from SRAM cell 10 through complementary bit lines including bit-line (BL) and bit-line bar (BLB).

SRAM cell 10 is powered through a positive power supply node VDD that has a positive power supply voltage. SRAM cell 10 is also connected to power supply voltage VSS (also denoted as VSS), which may be an electrical ground. Transistors PU-1 and PD-1 form a first inverter. Transistors PU-2 and PD-2 form a second inverter. The input of the first inverter is connected to transistor PG-1 and the output of the second inverter. The output of the first inverter is connected to transistor PG-2 and the input of the second inverter.

It is appreciated that FIG. 1 illustrates a six-transistor SRAM cell (which is a single-port SRAM cell) as an example, the concept of the present application, however, may be applied to other types of SRAM cells such as eight-transistor SRAM cells, ten-transistor SRAM cells, and the like, and may also be applied to dual-port SRAM cells.

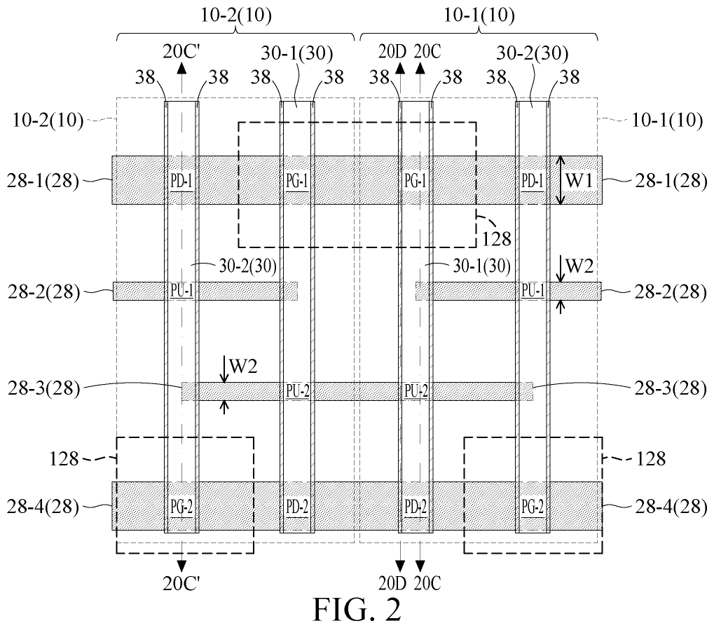

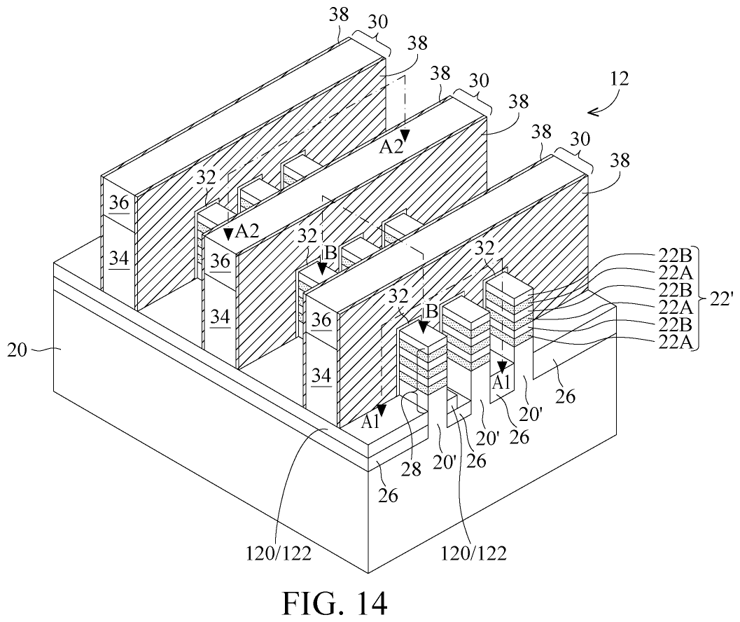

FIG. 2 illustrates an example schematic top view during an intermediate stage in the formation of SRAM cells in accordance with some embodiments. The intermediate stage shown in FIG. 2 corresponds to the process as shown in FIG. 14, as will be discussed subsequently. The illustrated region includes two SRAM cells 10 (including 10-1 and 10-2) abutting to each other. Each of the SRAM cells 10-1 and 10-2 includes six transistors as discussed referring to FIG. 1. In the following discussion, SRAM cell 10-1 is discussed as an example, while the discussion is also applicable to other SRAM cells.

In accordance with some embodiments, SRAM cell 10-1 includes four protruding fins 28 (including protruding fins 28-1, 28-2, 28-3, and 28-4), which will be discussed referring to subsequent figures. The transistors that are to be formed (and have not been formed yet during the stage as shown in FIG. 2) based on the protruding fins 28-1, 28-2, 28-3, and 28-4 are marked.

In accordance with some embodiments, to tune the performance of the transistors, the widths W1 of pass-gate transistors PG-1 and PG-2 and pull-down transistors PD-1 and PD-2 are greater than the widths W2 of pull-up transistors PU-1 and PU-2. The ratio W1/W2 may be in the range between about 1.2 and about 3 in accordance with some embodiments.

In accordance with some embodiments, dummy gate stacks 30 (including dummy gate stacks 30-1 and 30-2) are formed over protruding fins 28-1, 28-2, 28-3, and 28-4. The lengthwise directions of dummy gate stacks 30 are perpendicular to the lengthwise direction of protruding fins 28. Gate spacers 38 are formed on the opposing sidewalls of dummy gate stacks 30. In accordance with some embodiments, dummy gate stacks 30 are on the fin ends of protruding fins 28-2.

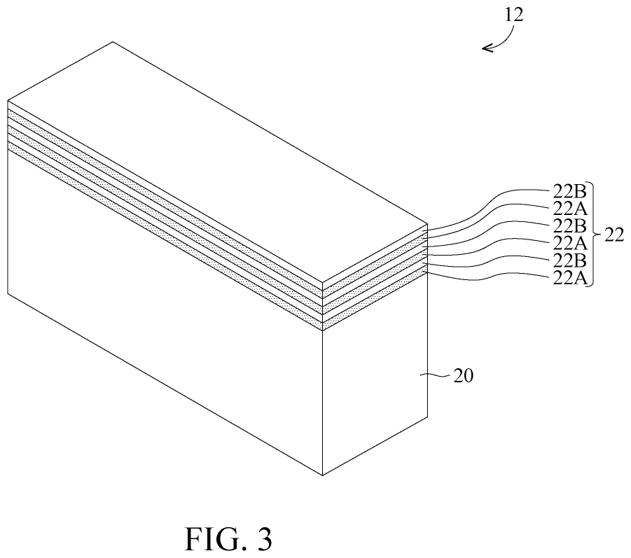

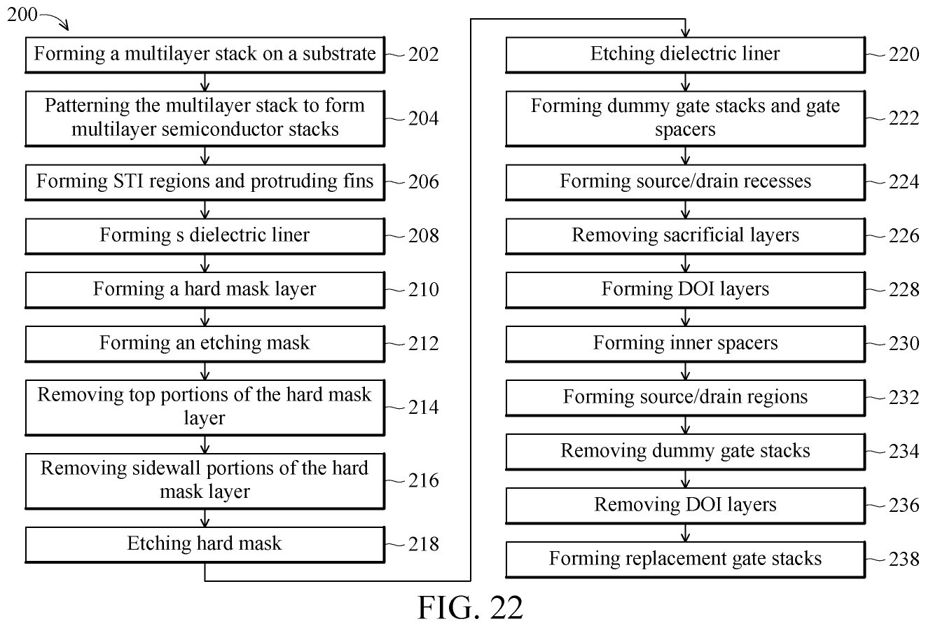

FIG. 3 through FIGS. 20A, 20B, 20C, and 20D illustrate the views of intermediate stages in the formation of an SRAM cell in accordance with some embodiments of the present disclosure. The corresponding processes are also reflected schematically in the process flow 200 as shown in FIG. 22.

FIGS. 3, 4, and 5A schematically illustrate the example formation process of protruding fins 28 in accordance with some embodiments. It is appreciated that the structures shown in FIGS. 3, 4, and 5A are merely shown to reflect how protruding fins are formed. The relationship (such as the relative positions and sizes) of the actual protruding fins for forming SRAM cells, however, is not shown in FIGS. 3, 4, and 5A.

Referring to FIG. 3, a perspective view of wafer 12 is shown. Wafer 12 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 22. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like.

A second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

The deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description.

In accordance with some embodiments, there may be some pad oxide layer(s) and hard mask(s) (not shown) formed over multilayer stack 22. These layers are patterned, and are used for the subsequent patterning of multilayer stack 22.

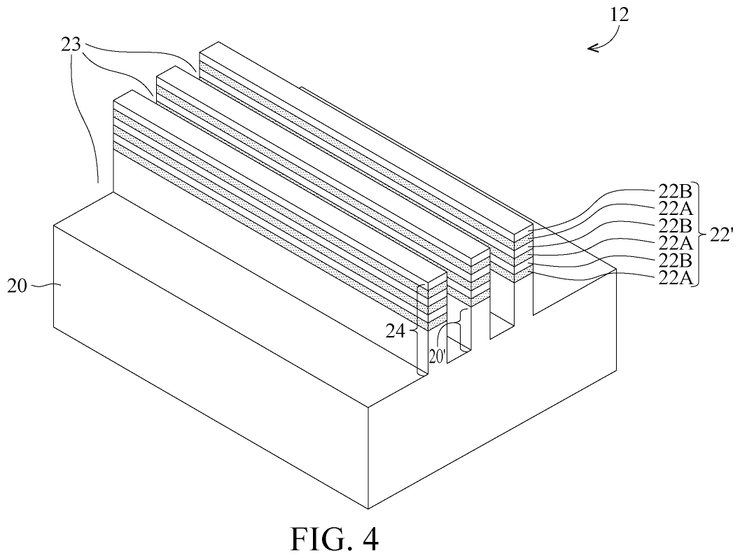

Referring to FIG. 4, multilayer stack 22 and a portion of the underlying substrate 20 are patterned in an etching process(es), so that trenches 23 are formed. The respective process is illustrated as process 204 in the process flow 200 shown in FIG. 22. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

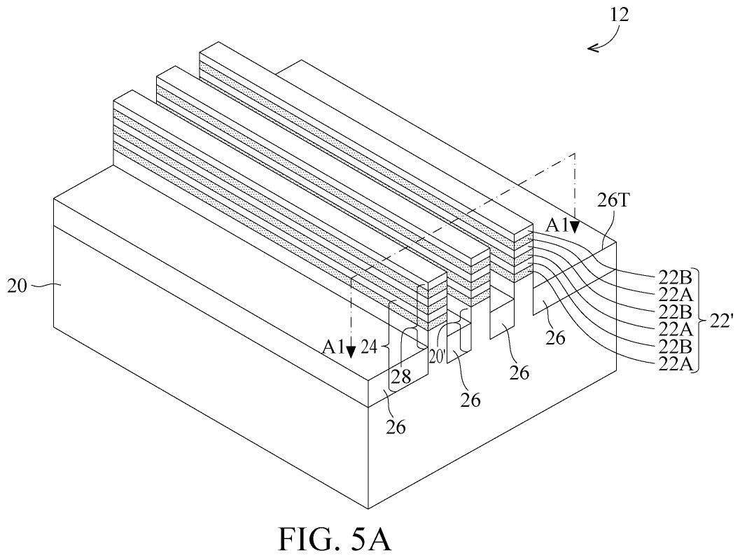

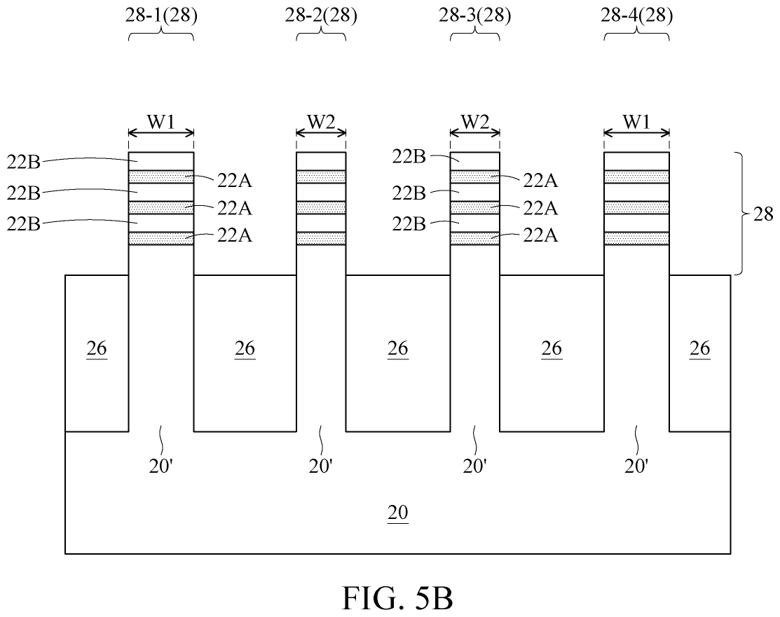

FIG. 5A illustrates the formation of isolation regions 26, which are also referred to as Shallow Trench Isolation (STI) regions throughout the description. The respective process is illustrated as process 206 in the process flow 200 shown in FIG. 22. The portions of the semiconductor substrate 20 lower than STI regions 26 are referred to as a bulk semiconductor substrate hereinafter. STI regions 26 may include a dielectric liner (refer to FIG. 5B), which may be a thermal oxide formed through the thermal oxidation of a surface layer of substrate 20. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20'.

FIG. 5B illustrates a cross-section that is perpendicular to the lengthwise direction of protruding fins, and the cross-section is similar to the cross-section A1-A1 in FIG. 5A. The cross-sectional view shown in FIG. 5B is obtained from the cross-section 20C-20C as shown in FIG. 2. Accordingly, protruding fins 28-1, 28-2, 28-3, and 28-4 are illustrated in a same cross-section. Furthermore, protruding fins 28-2 and 28-3 are shown as being narrower than protruding fins 28-1 and 28-4 in accordance with some embodiments. The illustrated protruding fin 28-2 is a line-end portion (as shown in FIG. 2) that is directly under the subsequently formed dummy gate stack 30-1.

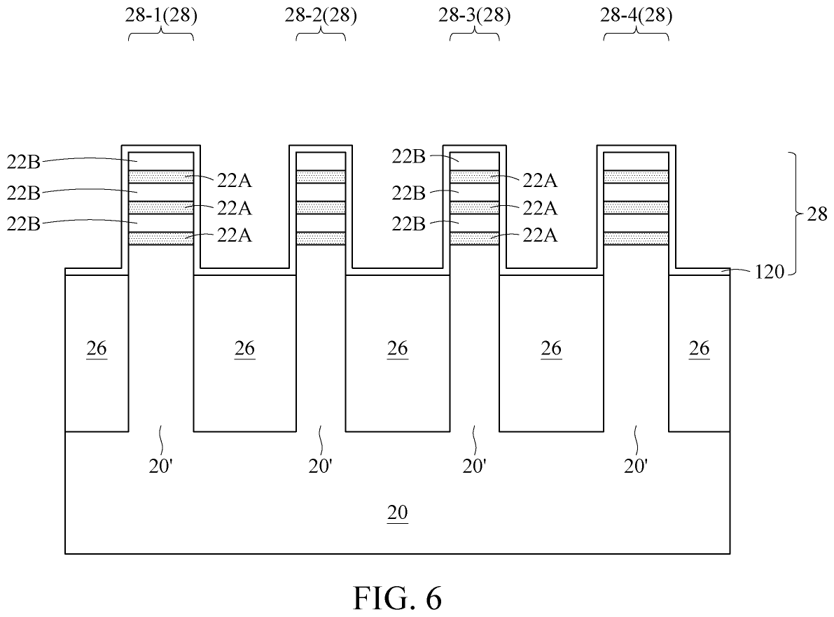

Referring to FIG. 6, dielectric layer 120 (also referred to as a dielectric liner) is formed. The respective process is illustrated as process 208 in the process flow 200 shown in FIG. 22. The material of dielectric layer 120 may be the same as or different from that of STI regions 26. In accordance with some embodiments, dielectric layer 120 comprises silicon oxide, while other materials such as SiOC, SiOCN, or the like may be adopted. The formation may include a deposition process, which may be a conformal deposition process such as ALD, CVD, or the like.

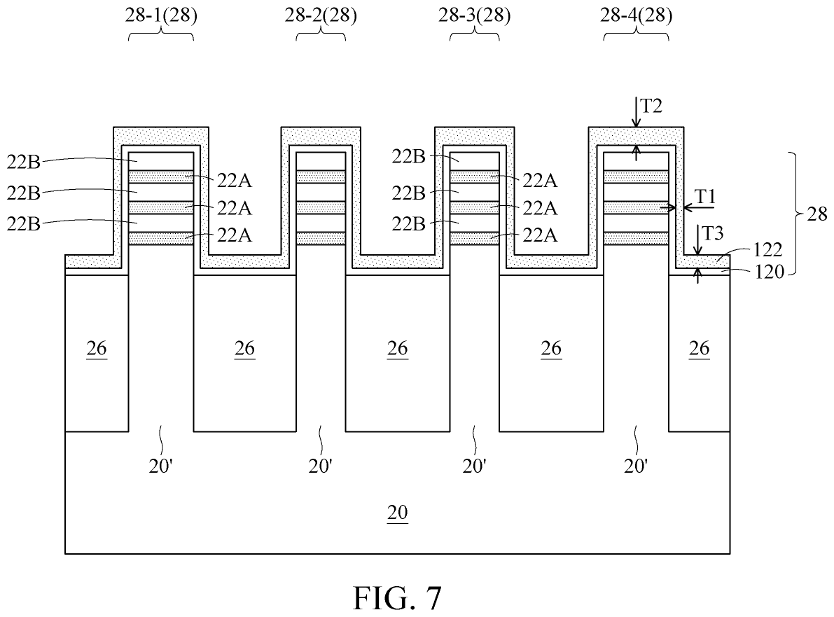

FIG. 7 illustrates the deposition of hard mask layer 122 (also referred to as protection layer 122 or hard mask 122). The respective process is illustrated as process 210 in the process flow 200 shown in FIG. 22. In accordance with some embodiments, hard mask layer 122 is formed as a non-conformal layer, which has sidewall portions having thickness T1, top portions having thickness T2, and bottom portions having thickness T3. The thicknesses T2 and T3 are greater than thickness T1. For example, the ratios T2/T1 and T3/T1 may be in the range between about 3 and about 20.

Hard mask layer 122 is formed of a dielectric material that is different from (and having a high etching selectivity relative to) the dielectric material of the underlying STI regions 26 and the subsequently formed disposable oxide interposers. The etching selectivity may be higher than about 10, for example. The material of the hard mask 122 is selected to have a high etching selectivity relative to some materials such as oxides, so that when these materials are etched, the hard mask layer 122 is not etched.

In accordance with some embodiments, hard mask layer 122 may be formed of or comprises a silicon-and-nitrogen containing dielectric material and/or a silicon-and-carbon containing dielectric material such as SiN, SiCN, SiON, SiCON, SiC, SiOC, or the like. Hard mask 122 may also comprise a high-k dielectric material such as Al₂O₃, HfO₂, HfSiO, ZrO₂, La₂O₃, Y₂O₃, or the like, or combinations thereof.

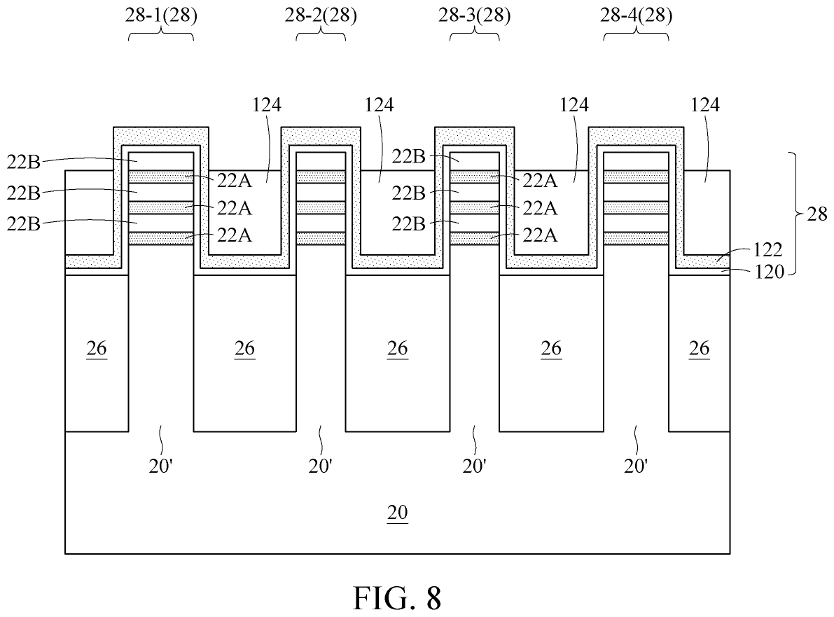

FIG. 8 illustrates the formation of sacrificial layer 124, which is used as an etching mask. The respective process is illustrated as process 212 in the process flow 200 shown in FIG. 22. In accordance with some embodiments, sacrificial layer 124 includes a material that may be used as a Bottom Anti-Reflective Coating (BARC), and may include a cross-linked photoresist, SiOC, or the like. The formation of sacrificial layer 124 may include a deposition (or dispensing) process, followed by a planarization process, and then an etch-back process. The top portions of the hard mask 122 are thus exposed.

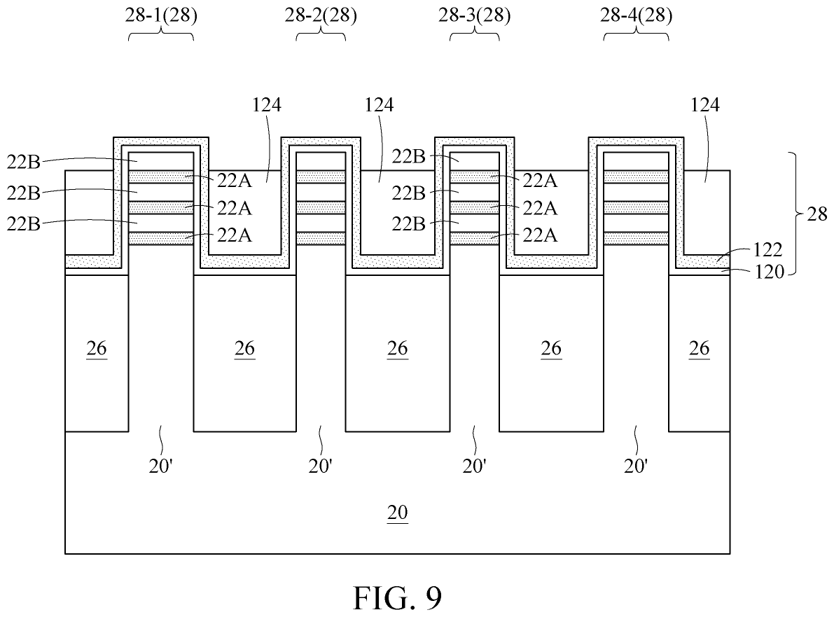

FIG. 9 illustrates the etching to remove some top portions of the hard mask 122. The respective process is illustrated as process 214 in the process flow 200 shown in FIG. 22. The etching may be performed through a dry etching process, a wet etching process, or the like. The etching chemical is selected to have a low etching rate on dielectric layer 120, and dielectric layer 120 may be used as an etch stop layer. After the etching process, the top portions of the hard mask 122 may be fully removed to expose dielectric layer 120, or may have thin portions remaining.

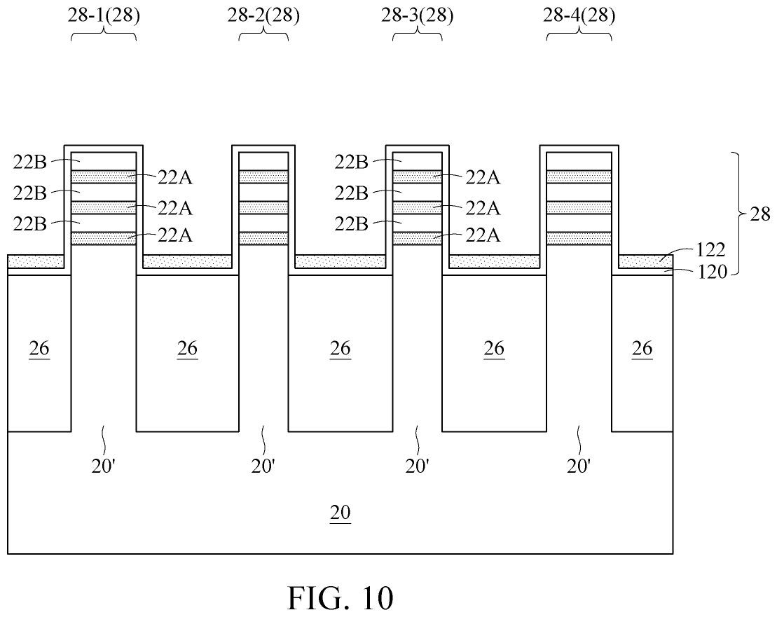

The sacrificial layer 124 is then removed, followed by an etching process to remove the top portions (when remaining) and sidewalls portions of hard mask layer 122. The respective process is illustrated as process 216 in the process flow 200 shown in FIG. 22. The resulting structure is shown in FIG. 10. The remaining sacrificial layer 124 extends from edges of protruding fins 28 to the nearest edges of their neighboring protruding fins 28. The etching process may be isotropic, and may be performed through a dry etching process or a wet etching process. Dielectric layer 120 is used as an etch stop layer.

In accordance with some embodiments, when the etching is stopped, the remaining hard mask layer 122 is not too thick and not too thin. A hard mask layer 122 that is too thin posts a challenge to the process control, and non-uniformity throughout the wafer may cause the hard mask layer 122 in some portions of the wafer to be etched fully or too thin, and not able to protect the underlying STI regions in the subsequent sheet formation. A hard mask layer 122 that is too thick may result in the capacitance between the subsequently formed gate electrode and semiconductor strip 20′ to be too high due to the high dielectric constant of the hard mask layer 122. In accordance with some embodiments, the thickness of the remaining hard mask layer 122 is in the range between about 2 nm and about 10 nm.

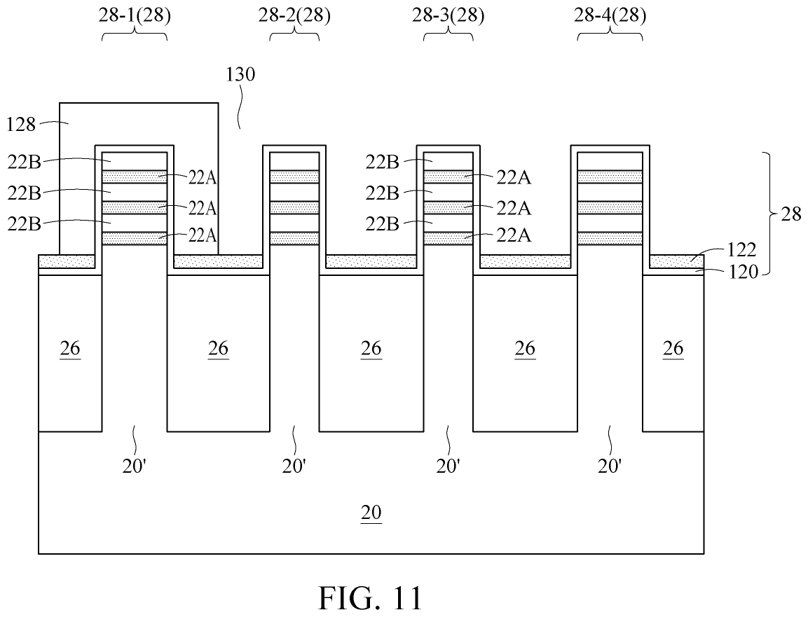

As shown in FIG. 11, etching mask 128 is formed and patterned. In accordance with some embodiments, etching mask 128 comprises a photoresist, which is patterned through a photolithography process. Opening 130 is thus formed in etching mask 128. The protruding fin 28-1 is directly under the remaining portion of etching mask 128. Referring to FIG. 2, etching mask 128 are schematically illustrated.

It is appreciated that the etching mask 128 are adjacent to the portions of protruding fins 28-1 and 28-4 that are used for forming pass-gate transistors, while the portions of protruding fins 28-1, 28-2, 28-3, and 28-4 that are used for forming pull-up transistors PU-1 and PU-2 and pull-down transistors PD-1 and PD-2 are directly under openings 130. Alternatively stated, openings 130 are located where etching mask 128 are not formed.

It is noted that in a cross-section 20C′-20C′ in FIG. 2, the cross-sectional view will be essentially the same as shown in FIG. 11, except that the cross-section shown in FIG. 11 reflects the view in cross-section 20C-20C when viewed from the left side of FIG. 2, and the cross-section shown in FIG. 11 also reflects the view in cross-section 20C′-20C′ when viewed from the right side of FIG. 2.

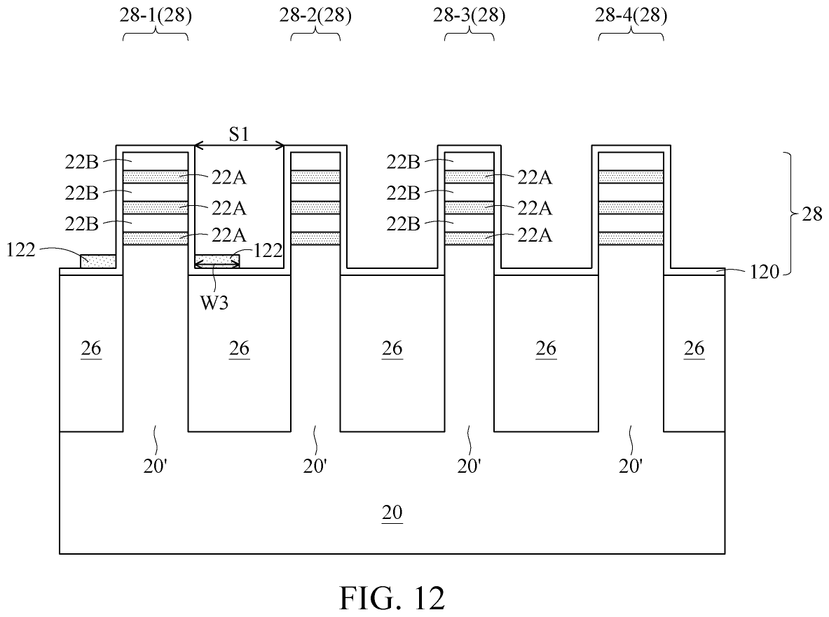

Referring to FIGS. 11 and 12, hard mask layer 122 is etched, and the portions of hard mask layer 122 adjacent to the future pass-gate transistors remain un-etched. The respective process is illustrated as process 218 in the process flow 200 shown in FIG. 22. The portions of the hard mask layer 122 not underlying etching mask 128 are etched and removed. In the etching of hard mask layer 122, dielectric layer 120 may also be used as an etch stop layer. The remaining portions of hard mask layer 122 are alternatively referred to as hard masks 122.

Etching mask 128 is then removed. The resulting structure is shown in FIG. 12. The remaining portions of hard mask layer 122 also include portions on the opposite sides of protruding fin 28-1, and on the opposite sides of some portions of protruding fins 28-4 as may be realized from FIG. 2. In accordance with some embodiments, the width W3 of hard masks 122 may be in the range between about ⅓ and about ⅔ of the spacing S1, which is the spacing between neighboring protruding fins 28-1 and 28-2.

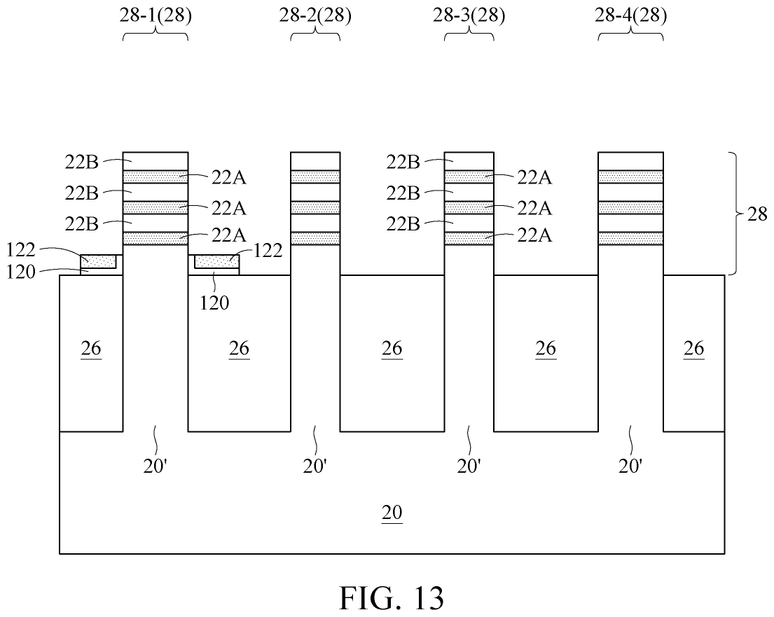

Next, as shown in FIG. 13, dielectric layer 120 is etched, so that protruding fins 28 are revealed. The respective process is illustrated as process 220 in the process flow 200 shown in FIG. 22. The etching may be performed through a dry etching process or a wet etching process. Dielectric layer 120 thus forms the dielectric liners of hard masks 122. Throughout the description, dielectric layer 120 and hard mask layer 122 are also collectively referred to as hard masks 120/122 or composite hard mask 120/122.

Referring to FIG. 14, which shows a perspective view, dummy gate stacks 30 and gate spacers 38 are formed on the top surfaces and the sidewalls of protruding fins 28. The respective process is illustrated as process 222 in the process flow 200 shown in FIG. 22. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask 36 over dummy gate electrode 34. Hard masks 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. The formation of dummy gate stacks 30 includes forming a dummy gate dielectric layer, depositing a dummy gate electrode layer over the dummy gate dielectric layer, depositing one or more hard masks, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

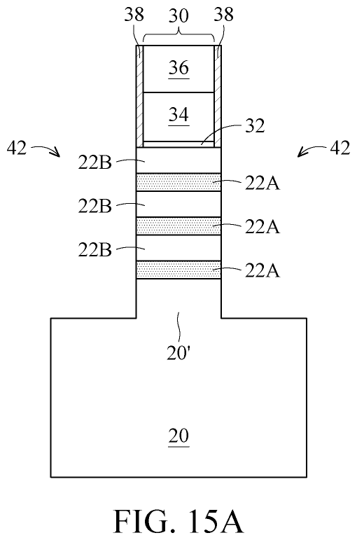

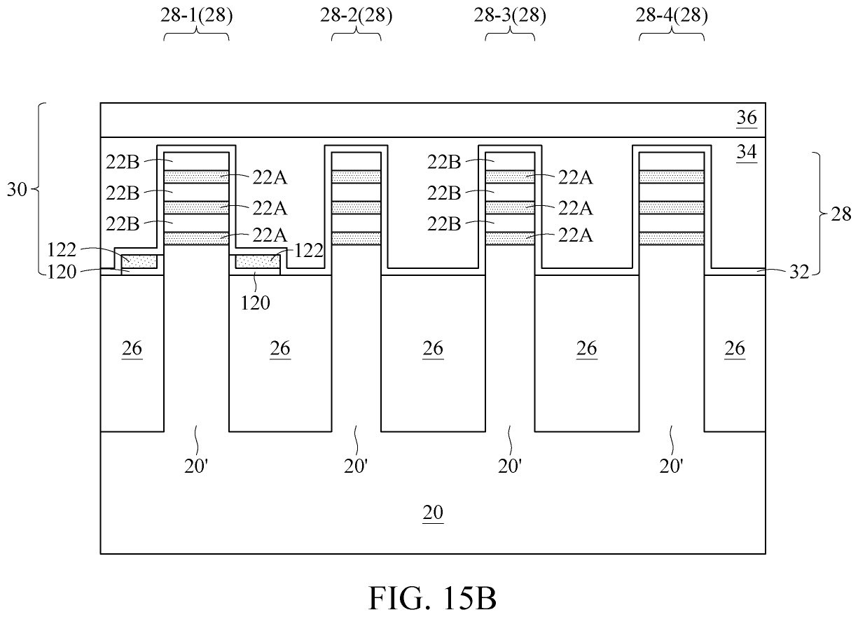

FIG. 15A illustrates a source/drain recessing process. The respective process is illustrated as process 224 in the process flow 200 shown in FIG. 22. FIG. 15A illustrates the cross-section B-B as shown in FIG. 14. The portions of protruding fins 28 that are not directly underlying dummy gate stacks 30 and gate spacers 38 are etched in an anisotropic etching process. Source/drain recesses 42 are thus formed, as shown in FIG. 15A. FIG. 15B illustrates the same cross-section as shown in FIG. 13, which cross-section corresponds to the cross-section A2-A2 (FIG. 14).

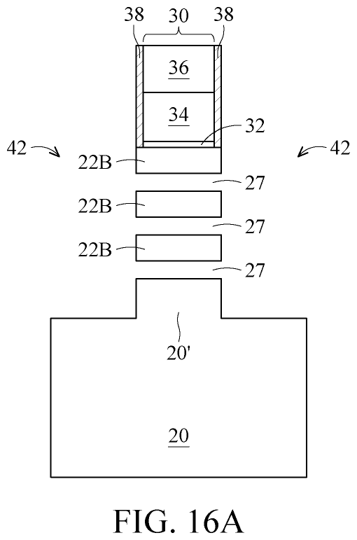

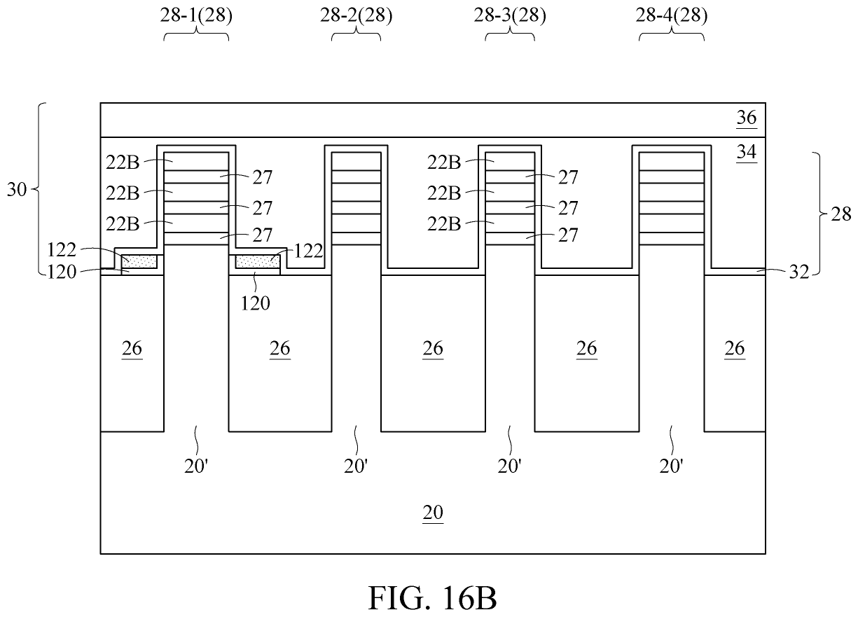

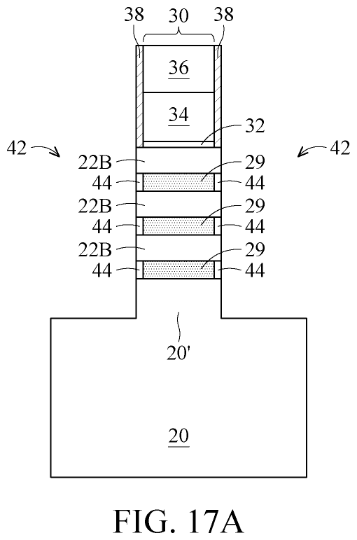

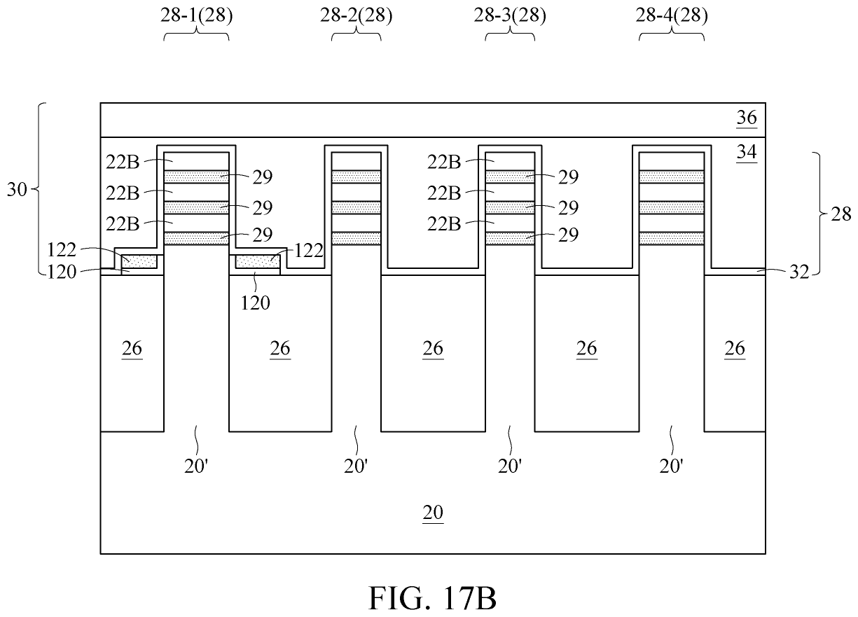

FIGS. 16A, 16B, 17A, and 17B illustrate the replacement of sacrificial layers 22A with disposable interposers 29. Referring to FIGS. 16A and 16B, which illustrate the cross-sections B-B and A2-A2, respectively in FIG. 14, the sacrificial layers 22A are first removed, forming openings 27 between nanostructures 22B. The respective process is illustrated as process 226 in the process flow 200 shown in FIG. 22.

Referring to FIGS. 17A and 17B, disposable interposers 29 are formed between nanostructures 22B. The respective process is illustrated as process 228 in the process flow 200 shown in FIG. 22. In accordance with some embodiments, disposable interposers 29 comprise an oxide such as silicon oxide, and thus may also be referred to as disposable oxide interposers (DOIs) 29. In accordance with other embodiments, other types of dielectric materials may be adopted.

The formation of disposable interposers 29 may include depositing a dielectric layer using a conformal deposition process such as ALD, CVD, or the like. The dielectric layer thus includes some portions filling openings 27, and some other portions outside of openings 27. An isotropic etching process is then performed to etch and remove the portions of the dielectric layer outside of openings 27. The remaining portions of the dielectric layer are thus the disposable interposers 29.

In accordance with alternative embodiments, the sacrificial layers 22A in the line-end portion of protruding fin 28-2 are not replaced with disposable interposers 29. This may be achieved by forming an etching mask to protect the line-end portions. In accordance with alternative embodiments, the sacrificial layers 22A in the line-end portions of protruding fin 28-2 are also replaced with disposable interposers 29, as shown in FIG. 17B.

Disposable interposers 29 are then laterally recessed and filled to form inner spacers 44 (FIG. 17A). The respective process is illustrated as process 230 in the process flow 200 shown in FIG. 22. The lateral recessing of disposable interposers 29 may be achieved through a wet etching process or a dry etching process. The wet etching process may be performed using a dip process, a spray process, a spin-on coating process, or the like. Nanostructures 22B are not etched.

Inner spacers 44 are then formed. In accordance with some embodiments, the formation of inner spacers 44 includes depositing a conformal dielectric layer, which extends into the lateral recesses. Next, an etching process (also referred to as a spacer trimming process) is performed to trim the portions of the dielectric layer outside of the lateral recesses, leaving the portions of the dielectric layer in the lateral recesses. The remaining portions of the dielectric layer are referred to as inner spacers 44.

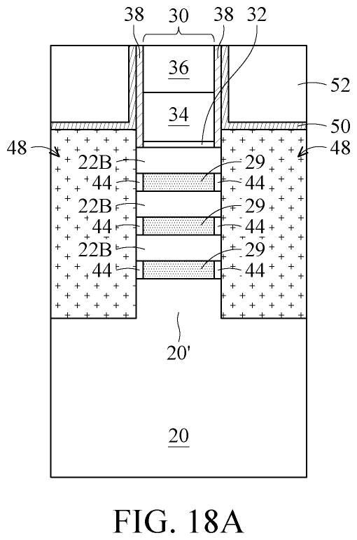

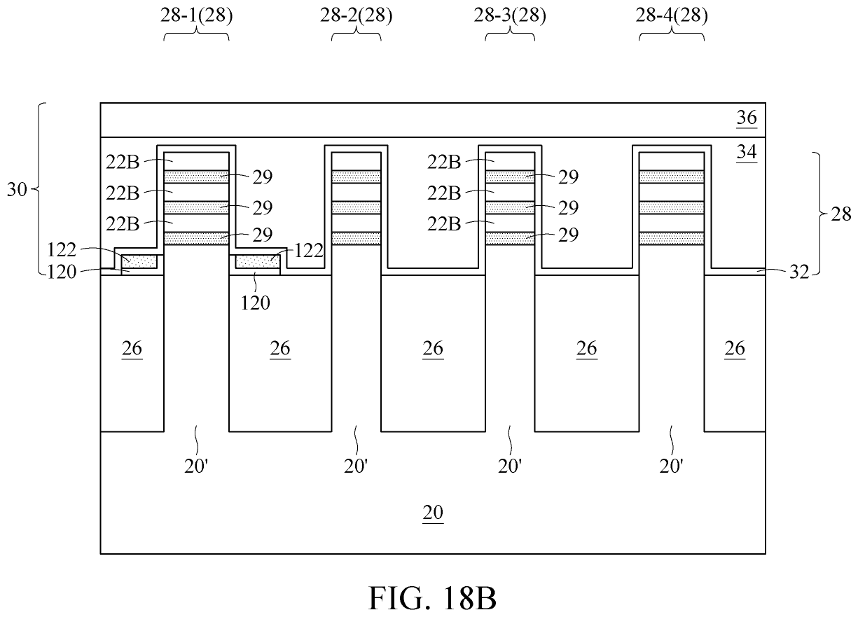

Referring to FIGS. 18A and 18B, epitaxial source/drain regions 48 are formed in recesses 42 through selective epitaxy. The respective process is illustrated as process 232 in the process flow 200 shown in FIG. 22. Depending on whether the resulting transistor is a p-type transistor or an n-type transistor, a p-type or an n-type impurity may be in-situ doped with the proceeding of the epitaxy. For example, when the resulting transistor is a p-type transistor, silicon germanium boron (SiGeB), silicon boron (SiB), or the like may be grown. Conversely, when the resulting transistor is an n-type transistor, silicon phosphorous (SiP), silicon carbon phosphorous (SiCP), or the like may be grown.

Contact Etch Stop Layer (CESL) 50 and Inter-Layer Dielectric (ILD) 52 are then formed. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may include silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIGS. 18A and 18B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

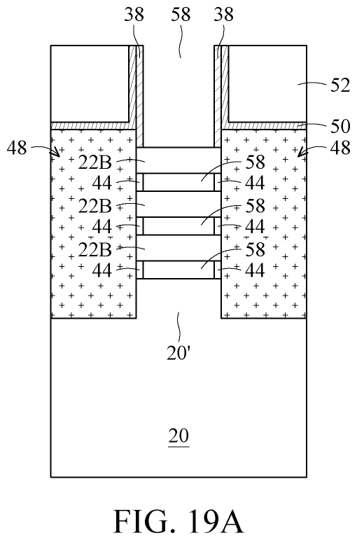

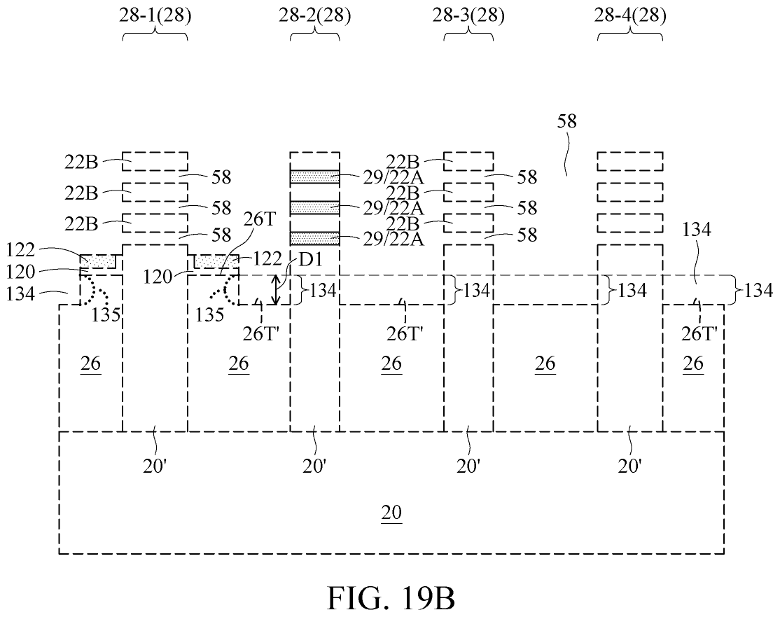

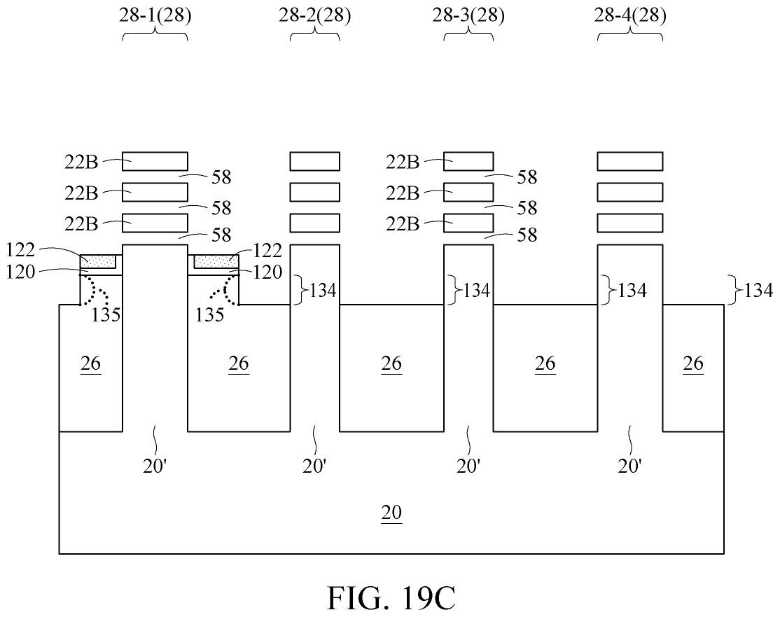

Next, dummy gate electrodes 34 and dummy gate dielectrics 32 (and hard masks 36, if remaining) are removed in one or more etching processes, so that recesses 58 are formed, as shown in FIGS. 19A, 19B, and 19C. The respective process is illustrated as process 234 in the process flow 200 shown in FIG. 22. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22', which include the future channel regions in subsequently completed transistors.

Disposable interposers 29 are then removed to extend recesses 58 between nanostructures 22B. The respective process is illustrated as process 236 in the process flow 200 shown in FIG. 22. Disposable interposers 29 may be removed by performing an isotropic etching process such as a wet etching process using etchants which are selective to the materials of disposable interposers 29, while nanostructures 22B and substrate 20 remain relatively un-etched as compared to disposable interposers 29. In accordance with some embodiments in which disposable interposers 29 include, for example, silicon oxide, the mixture of NF₃ and NH₃, the mixture of HF and NH₃, or HF may be used to remove disposable interposers 29.

In accordance with some embodiments, the disposable interposers 29 in the line-end portion of protruding fin 28-2 are not removed, as shown in FIG. 19B. This may be achieved by forming an etching mask to protect these disposable interposers 29. In accordance with alternative embodiments in which the line-end portion of protruding fin 28-2 comprises sacrificial layer 22A that are not replaced with disposable interposers 29, the sacrificial layers 22A in the line-end portion of protruding fin 28-2 are not removed, as shown in FIG. 19B. In accordance with yet alternative embodiments, the disposable interposers 29 in the line-end portion of protruding fin 28-2 are also removed, as shown in FIG. 19C.

In the etching of disposable interposers 29, the STI regions 26 directly under hard masks 122 are protected by hard masks 122 from the etching due to the high etching selectivity, which is the ratio of the etching rate of disposable interposers 29 to the etching rate of the hard masks 122. The STI regions 26 not protected by hard masks 122, on the other hand, are recessed. Accordingly, recesses 134 are formed, which are recessed from the original top surface 26T of STI regions 26. In accordance with some embodiments, the recessing distance D1 may be in the range between about 0.5 nm and about 5 nm.

It is appreciated that although the recesses 134 are illustrated as having sharp corners, the corners may be curved or may be sharp. For example, the recesses 134 may have a U-shape in the cross-sectional view. The portions of STI region 26 directly under recesses 134 have recessed top surface 26T′. In accordance with some embodiments, an entirety of top surface 26T′ is lower than an entirety of top surface 26T.

In accordance with some embodiments, undercuts 135 may be formed directly underlying hard mask 122, which undercuts 135 are shown using dashed lines. The lateral recessing distance of undercuts 135 may be in the range between about 0.5 nm and about 5 nm in accordance with some embodiments.

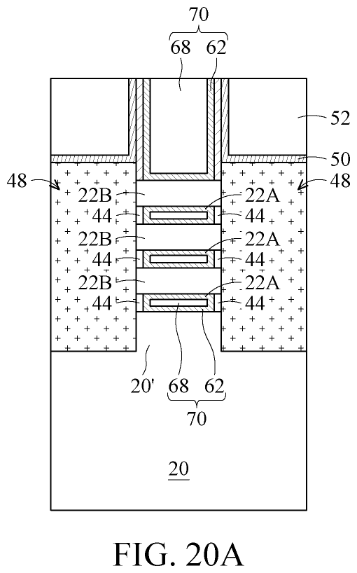

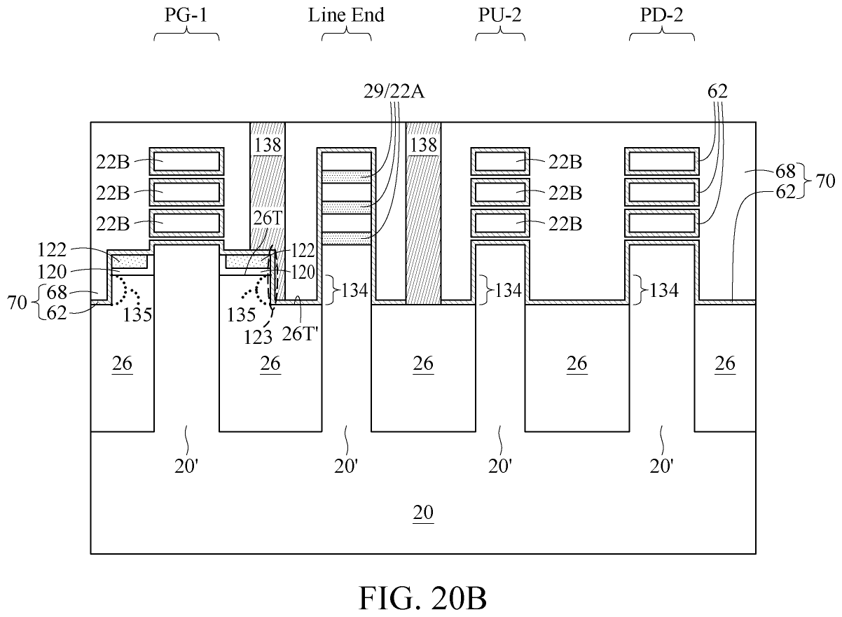

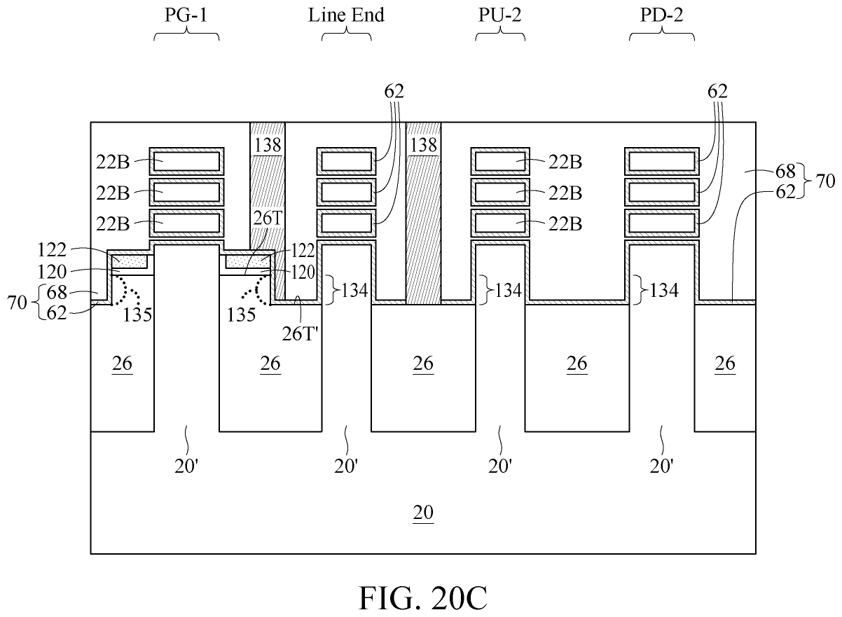

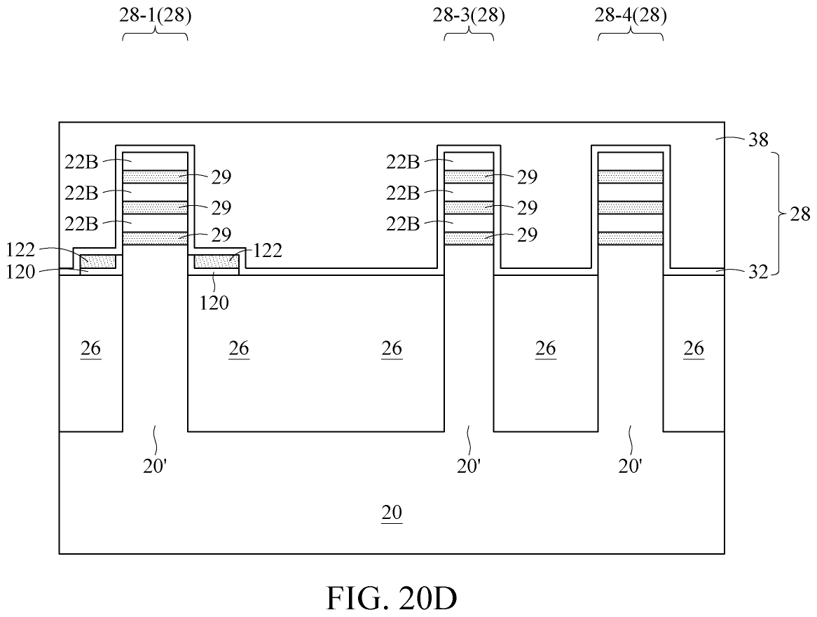

Referring to FIGS. 20A, 20B, and 20C, gate dielectrics 62 and gate electrodes 68 are formed, hence forming replacement gate stacks 70. The respective process is illustrated as process 238 in the process flow 200 shown in FIG. 22. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more high-k dielectric layers. For example, the high-k dielectric layer(s) may include a metal oxide or a silicate of hafnium, aluminum, zirconium, lanthanum, manganese, barium, titanium, lead, and combinations thereof. In accordance with some embodiments in which the interfacial layer is formed through oxidation, the high-k dielectric layer is in physical contact with the top surface and the sidewalls of the hard mask layer 122.

Gate electrodes 68 are formed over gate dielectrics 62. In the formation process, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′.

After the filling of recesses 58, a planarization process such as a CMP process or a mechanical grinding process is performed to remove the excess portions of the gate dielectrics 62 and gate electrodes 68, which excess portions are over the top surface of ILD 52. Gate electrodes 68 and gate dielectrics 62 are collectively referred to as gate stacks 70 of the resulting transistors.

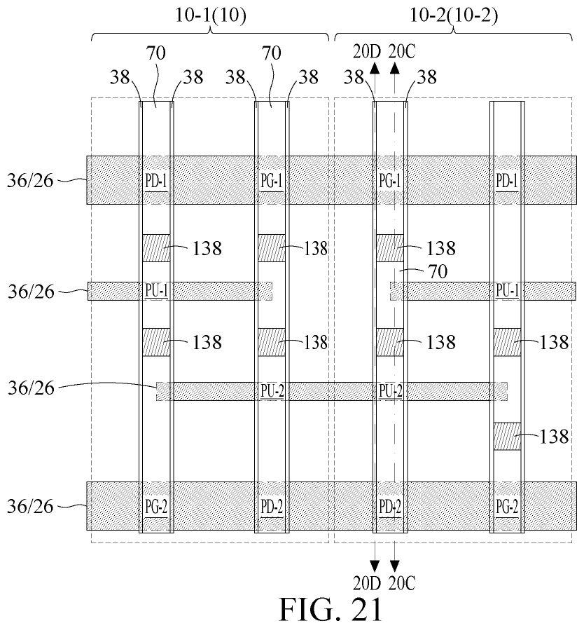

FIG. 21 illustrates a top view of the SRAM cells. Besides the transistors and gate stacks, gate isolation regions 138, which are also cut-metal-gate regions, are also illustrated. The gate isolation regions 138 are formed of a dielectric material(s). The gate isolation regions 138 are used to isolate gate stacks that are not intended to be interconnected apart from each other.

In accordance with some embodiments, as shown in FIGS. 20B and 20C, gate isolation regions 138 land on the top surfaces of gate dielectrics 62, with gate dielectrics 62 being used as an etch stop layer in the formation of gate isolation regions 138. In accordance with alternative embodiments, gate isolation regions 138 penetrate through gate dielectrics 62 and land on STI regions 26, and may possibly land on hard mask 122 (refer to the gate isolation regions 138 on the left of FIGS. 20B and 20C). In accordance with these embodiments, some vertical portions of the portions of gate dielectrics 62 in regions 123 may be left to contact the vertical edges of the respective gate isolation regions 138.

FIG. 20B illustrates the cross-sectional view of the SRAM cell, wherein the cross-sectional view is obtained from cross-section 20C-20C as shown in FIG. 21. The cross-section cuts through the gate stacks and the line-end portion of the protruding fins. FIG. 20B illustrates an embodiment in which the line portions 29/22A, which include DOIs 29 or sacrificial layers 22A, depending on the process adopted. The transistors PG-1, the line-end portion, pull-up transistor PU-2, and pull-down transistor PD-2 are in the cross-section as illustrated.

In accordance with some embodiments, all of the pass-gate transistors in an SRAM cell, and in all SRAM cells of a SRAM array include hard masks 122 on opposite sides of their channel regions (semiconductor nanostructures 22B). Conversely, all of the pull-up transistors and pull-down transistors in an SRAM cell, and in all SRAM cells of a SRAM array do not include hard masks 122 on opposite sides of their channel regions.

FIG. 20C illustrates an embodiment in which the replacement gate stack 70 also extend into the line-end portion of the protruding fin 28-2.

FIG. 20D illustrates a cross-sectional view of the SRAM cell, wherein the cross-sectional view is obtained from cross-section 20D-20D as shown in FIG. 21. The cross-section is obtained from gate spacer 38. Hard mask layer 122 also comprises portions in the illustrated cross-section in FIG. 20D.

The embodiments of the present disclosure have some advantageous features. By forming and then partially removing hard masks from opposite sides of the protruding structures (and the channel regions) of pull-up transistors and pull-down transistors, the replacement gate stacks of the pull-up transistors and pull-down transistors extend lower than the replacement gate stacks of the pass-gate transistors. The pull-up transistors and pull-down transistors thus may have better gate control, while the pass-gate transistors may have smaller bit-line capacitance. Accordingly, the performance of the pass-gate transistors may be tuned separately from the performance of the pull-up transistors and pull-down transistors.

In accordance with some embodiments of the present disclosure, a method comprises forming a shallow trench isolation region in a semiconductor substrate; forming a first protruding fin and a second protruding fin higher than, and on opposing sides of, the shallow trench isolation region; forming a hard mask over the shallow trench isolation region, wherein the hard mask comprises a first portion closer to the first protruding fin and overlapping a first part of the shallow trench isolation region; and a second portion closer to the second protruding fin and overlapping a second part of the shallow trench isolation region; patterning the hard mask to remove the second portion of the hard mask, and leaving the first portion of the hard mask over the first part of the shallow trench isolation region; and forming a gate stack over the first portion of the hard mask, wherein the gate stack and a part of the first protruding fin collectively form a first transistor.

In an embodiment, the first protruding fin comprises a first semiconductor layer; a second semiconductor layer overlapping the first semiconductor layer; and a disposable interposer between the first semiconductor layer and the second semiconductor layer, wherein the method further comprises removing the disposable interposer through etching, wherein when the disposable interposer is removed, the second part of the shallow trench isolation region is recessed, and the first part of the shallow trench isolation region is protected from being etched. In an embodiment, the disposable interposer and the shallow trench isolation region comprise a same dielectric material.

In an embodiment, the shallow trench isolation region comprises silicon oxide, and the hard mask comprises silicon nitride. In an embodiment, the gate stack comprises a gate dielectric and a gate electrode over the gate dielectric, and wherein the gate dielectric contacts the hard mask. In an embodiment, the gate dielectric physically contacts a top surface and a sidewall of the hard mask. In an embodiment, after the hard mask is patterned, the hard mask comprises a third portion overlapping a second shallow trench isolation region, wherein the third portion is on an opposite side of the first protruding fin than the first portion of the hard mask.

In an embodiment, the hard mask comprises a third portion and a fourth portion on opposite sides of a third protruding fin, wherein after the hard mask is patterned, both of the third portion and the fourth portion are removed. In an embodiment, the first transistor is a pass-gate transistor of a SRAM cell. In an embodiment, the method further comprises forming a second transistor for the SRAM cell, wherein the second transistor is selected from a pull-up transistor and a pull-down transistor of the SRAM cell, and wherein in the patterning the hard mask, portions of the hard mask on opposite sides of a channel region of the second transistor are removed.

In accordance with some embodiments of the present disclosure, a structure comprises a bulk semiconductor substrate; a first shallow trench isolation region over the bulk semiconductor substrate, wherein the first shallow trench isolation region comprises a first portion and a second portion; a first semiconductor strip comprising a first edge contacting the first shallow trench isolation region, wherein the first portion of the first shallow trench isolation region is laterally between the first semiconductor strip and the second portion of the first shallow trench isolation region, and a first top surface of the first portion is higher than a second top surface of the second portion; a composite hard mask in contact with the first edge of the first semiconductor strip, wherein the composite hard mask is over the first portion of the first shallow trench isolation region; and a first gate stack overlapping the composite hard mask and the first shallow trench isolation region, wherein a portion of the first gate stack overlapping the second portion of the first shallow trench isolation region is lower than the composite hard mask, and wherein the first gate stack is a portion of a first transistor.

In an embodiment, the first shallow trench isolation region comprises silicon oxide, and the composite hard mask comprises silicon nitride. In an embodiment, the structure further comprises a SRAM cell comprising the first transistor as a pass-gate transistor; a second transistor comprising a second gate stack; and a second shallow trench isolation region under the second gate stack, wherein the structure is free from a same material as the composite hard mask between the second shallow trench isolation region and the second gate stack. In an embodiment, the second transistor is selected from a group consisting of a pull-up transistor and a pull-down transistor of the SRAM cell.

In an embodiment, the composite hard mask comprises a dielectric liner comprising a first dielectric material; and a dielectric region comprising a second dielectric material different from the first dielectric material, wherein the dielectric region is over the dielectric liner. In an embodiment, the structure further comprises a second semiconductor strip on an opposite side of the first shallow trench isolation region than the first semiconductor strip, wherein the second top surface of the second portion extends to the second semiconductor strip. In an embodiment, an entirety of the second top surface of the second portion is lower than an entirety of the first top surface of the first portion.

In accordance with some embodiments of the present disclosure, a structure comprises a bulk semiconductor substrate; a first dielectric isolation region, a second dielectric isolation region, a third dielectric isolation region, and a fourth dielectric isolation region over the bulk semiconductor substrate; a first semiconductor strip between and contacting the first dielectric isolation region and the second dielectric isolation region; a first semiconductor layer overlapping and spaced apart from the first semiconductor strip; a first gate stack over and contacting the first dielectric isolation region, the second dielectric isolation region, and the first semiconductor strip, wherein the first gate stack encircles the first semiconductor layer; a composite hard mask between the first gate stack and the first dielectric isolation region; a second semiconductor strip between and contacting the third dielectric isolation region and the fourth dielectric isolation region; a second semiconductor layer overlapping and spaced apart from the second semiconductor strip; and a second gate stack over and contacting the third dielectric isolation region and the fourth dielectric isolation region, wherein the second gate stack encircles the second semiconductor layer, and wherein an interface between the second gate stack and the third dielectric isolation region extends to opposite sidewalls of the third dielectric isolation region.

In an embodiment, the first dielectric isolation region comprises a first top surface and a second surface, wherein the first top surface is laterally between the first semiconductor strip and the second surface, and the second surface is lower than the first top surface. In an embodiment, the first top surface is underlying the composite hard mask, and forms an additional interface with the composite hard mask.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure comprising:
a semiconductor substrate;
a shallow trench isolation region in the semiconductor substrate, wherein the shallow trench isolation region comprises a first part and a second part joined to the first part;
a first semiconductor region and a second semiconductor region on opposing sides of, and contacting the first part and the second part, respectively, of the shallow trench isolation region;
a hard mask comprising portions on opposite side of and contacting the first semiconductor region, wherein the hard mask is over and contacting the first part of the shallow trench isolation region; and
a gate stack comprising:
a gate dielectric comprising:
a first portion overlapping and contacting the hard mask; and
a second portion overlapping and contacting the second part of the shallow trench isolation region; and
a gate electrode over the gate dielectric, wherein the first portion of the gate dielectric and the gate electrode collectively form portions of a first transistor.

2. The structure of claim 1, wherein the hard mask comprises a first material different from a second material of the shallow trench isolation region.

3. The structure of claim 1, wherein the first transistor and the second semiconductor region are comprised in a static random access memory cell.

4. The structure of claim 3, wherein the first transistor is a pass-gate transistor of the static random access memory cell.

5. The structure of claim 3, wherein the second semiconductor region is a line end portion of a pull-up transistor of the static random access memory cell.

6. The structure of claim 1 further comprising a gate isolation region over and contacting the gate dielectric.

7. The structure of claim 6, wherein the gate isolation region comprises a bottom surface that contacts the gate dielectric and forms a step.

8. The structure of claim 1, wherein:
the first portion of the gate dielectric overlaps a first top surface of the first part of the shallow trench isolation region; and
the second portion of the gate dielectric overlaps and contacts a second top surface of the second part of the shallow trench isolation region, and wherein the second top surface is lower than the first top surface.

9. The structure of claim 1, wherein the gate dielectric further contacts a sidewall of the hard mask.

10. The structure of claim 1, wherein the hard mask has a multilayer structure.

11. A structure comprising:
a bulk semiconductor substrate;
a shallow trench isolation region over the bulk semiconductor substrate, wherein the shallow trench isolation region comprises a first portion and a second portion;
a first semiconductor strip contacting a first edge of the shallow trench isolation region;
a second semiconductor strip contacting a second edge of the shallow trench isolation region, wherein the second edge is opposite to the first edge; and
a first gate stack comprising:
a gate dielectric contacting a top portion of the first semiconductor strip to form a first vertical interface, and contacting a top portion of the second semiconductor strip to form a second vertical interface, wherein the second vertical interface is taller than the first vertical interface; and
a gate electrode over the gate dielectric.

12. The structure of claim 11 further comprising a hard mask comprising:
a first sidewall vertically aligned to the first edge of the shallow trench isolation region; and
a second sidewall interfacing the gate dielectric to form a third vertical interface.

13. The structure of claim 11, wherein the first portion of the shallow trench isolation region comprises a sidewall that connects a top surface of the first portion of the shallow trench isolation region to a top surface of the second portion of the shallow trench isolation region.

14. The structure of claim 11 further comprising a hard mask overlapping the first portion of the shallow trench isolation region, wherein the shallow trench isolation region comprises silicon oxide, and the hard mask comprises silicon nitride.

15. The structure of claim 11, wherein the first semiconductor strip and the second semiconductor strip are comprised in a static random access memory cell.

16. The structure of claim 15, wherein the static random access memory cell comprises a pass-gate transistor that comprises a channel region, and the channel region overlaps the first semiconductor strip.

17. A structure comprising:
a bulk semiconductor substrate;
a plurality of dielectric isolation regions over the bulk semiconductor substrate;
a first semiconductor strip, a second semiconductor strip, and a third semiconductor strip between and contacting respective ones of the plurality of dielectric isolation regions, wherein in a cross-section of the structure, the second semiconductor strip is between the first semiconductor strip and the third semiconductor strip, and wherein a dielectric isolation region of the plurality of dielectric isolation regions comprises:
a first top surface joined to the first semiconductor strip;
a second top surface joined to the second semiconductor strip; and
a sidewall connecting the first top surface to the second top surface;
a first transistor comprising a first semiconductor nanostructure that overlaps the first semiconductor strip;
a second semiconductor nanostructure that overlaps the second semiconductor strip; and
a second transistor comprising a third semiconductor nanostructure that overlaps the third semiconductor strip.

18. The structure of claim 17 further comprising a hard mask over and contacting the dielectric isolation region, wherein the hard mask comprises:
a first edge contacting the first semiconductor strip; and
a second edge vertically aligned to the sidewall of the dielectric isolation region.

19. The structure of claim 18 further comprising:
a first gate stack over the first top surface of the dielectric isolation region;
a second gate stack over the second top surface of the dielectric isolation region; and
a gate isolation region over the sidewall of the dielectric isolation region.

20. The structure of claim 17, wherein the first transistor is a pass-gate transistor of a static random access memory cell, and the second transistor is a pull-up transistor or a pull-down transistor of the static random access memory cell.
